(19) United States
(12) Patent Application Publication
(10) Pub. No.: US 2026/0005079 A1
(43) Pub. Date: Jan. 1, 2026

(54) THIN GLASS CORE PANELS IN CIRCUIT DEVICE PACKAGING

(71) Applicant: Intel Corporation, Santa Clara, CA (US)

(72) Inventors: Jeremy Ecton, Gilbert, AZ (US); Kristof Darmawikarta, Chandler, AZ (US); Brandon Marin, Gilbert, AZ (US); Gang Duan, Chandler, AZ (US); Srinivas Pietambaram, Chandler, AZ (US); Benjamin Duong, Phoenix, AZ (US); Soham Agarwal, Chandler, AZ (US); Kari Hernandez, Phoenix, AZ (US); Pratyush Mishra, Tempe, AZ (US); Pratyasha Mohapatra, Tempe, AZ (US); Bohan Shan, Chandler, AZ (US); Hiroki Tanaka, Gilbert, AZ (US)

(73) Assignee: Intel Corporation, Santa Clara, CA (US)

(21) Appl. No.: 18/758,880

(22) Filed: Jun. 28, 2024

(51) Int. Cl. H01L 23/08; H01L 21/762; H01L 23/498; H01L 23/528

(52) U.S. Cl. CPC H01L 23/08; H01L 21/76224; H01L 23/49827; H01L 23/5283

(57) ABSTRACT

Thin glass cores for integrated circuit (IC) packages. Recesses in a glass core may be selectively etched into a frontside and/or backside of the glass core to locally reduce the thickness of glass. A dielectric material may be applied over the glass to backfill the recesses. The glass may then be further thinned from a same side as the recess to reduce the thickness of regions outside of the recesses. Alternatively, the glass may then be further thinned from a side of the glass opposite the recess to reduce the thickness of regions outside of the recesses and also remove the lesser thickness of glass remaining at the location of the recess. Panels comprising the thin glass core may then be built-up with routing metallization and assembled with IC die.

### BACKGROUND

In integrated circuit (IC) device manufacturing, IC packaging comprises assembling an IC that has been monolithically fabricated on a chip (die or chiplet) comprising a semiconducting material into a “package” that can protect the IC chip from physical damage and support electrical contacts that connect the IC to a scaled host component. Multiple heterogenous chips can be similarly assembled, for example, into a multi-chip package (MCP).

A package substrate provides a means to connect chiplets and passives with extremely high I/O count to a host component, such as a printed circuit board (PCB). Package substrates are often built around a fiberglass resin core with copper on both sides, typically referred to as a copper clad laminate (CCL). The CCL facilitates the creation of redistribution metallization layers (RDL) that connect through the substrate core with plated through holes (PTH). The various RDLs are separated from each other by organic dielectric layers, known as build-up films, which are typically dry film laminates.

Package substrate processing has evolved beyond PCB processing through the use of specialized tooling, such laser drills, and lithography steppers that can reduce RDL feature dimensions to below 5 μm line/space (l/s). However, a transition from CCL cores to glass cores may be necessary to further scale feature sizes (e.g., to 2 μm l/s, and below) and/or to enable larger package substrate sizes (e.g., exceeding 120 mm×120 mm). In the manufacture of glass cored package substrates, it is advantageous to minimize the thickness of the glass core, for example to reduce the depth of conductive through-glass vias so that the lateral pitch of such vias may be scaled down and their density increased.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating methods of forming an IC die package comprising a package substrate with a thin glass core, in accordance with some embodiments;

FIG. 2A and 2B are plan and cross-sectional views of a glass core, in accordance with some embodiments;

FIG. 3A, 3B and 3C are plan and cross-sectional views illustrating formation of recesses in a glass core, in accordance with some embodiments;

FIG. 4A, 4B and 4C are plan and cross-sectional views illustrating the formation of through vias within thin regions of a glass core, in accordance with some embodiments;

FIG. 5A, 5B and 5C are plan and cross-sectional views illustrating reconstitution of glass cores, in accordance with some embodiments;

FIG. 6A, 6B and 6C are plan and cross-sectional views illustrating a secondary thinning of a glass core, in accordance with some embodiments;

FIG. 7A, 7B and 7C are plan and cross-sectional views illustrating package build-up upon a thin glass core, in accordance with some embodiments;

FIG. 8A, 8B and 8C are plan and cross-sectional views illustrating IC die assembly upon a package substrate including a thin glass core, in accordance with some embodiments;

FIG. 9A and 9B are plan and cross-sectional views illustrating formation of recesses in a glass core, in accordance with some alternative embodiments;

FIG. 10A and 10B are plan and cross-sectional views illustrating reconstitution of glass cores, in accordance with some alternative embodiments;

FIG. 11A and 11B are plan and cross-sectional views illustrating secondary thinning of a glass core, in accordance with some alternative embodiments;

FIG. 12A and 12B are plan and cross-sectional views illustrating the formation of conductive through vias within recessed regions of a glass core, in accordance with some alternative embodiments;

FIG. 13A and 13B are plan and cross-sectional views illustrating backside encapsulation of a glass core, in accordance with some alternative embodiments;

FIG. 14A and 14B are plan and cross-sectional views illustrating package build-up upon a thin glass core, in accordance with some alternative embodiments;

FIG. 15A and 15B are plan and cross-sectional views illustrating IC die assembly upon a package substrate including a thin glass core, in accordance with some alternative embodiments;

FIG. 16 illustrates a mobile computing platform and a data server machine including an IC package assembly comprising a thin glass core, in accordance with some embodiments; and

FIG. 17 is a functional block diagram of an electronic computing device that may be included with a mobile or server computing platform, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

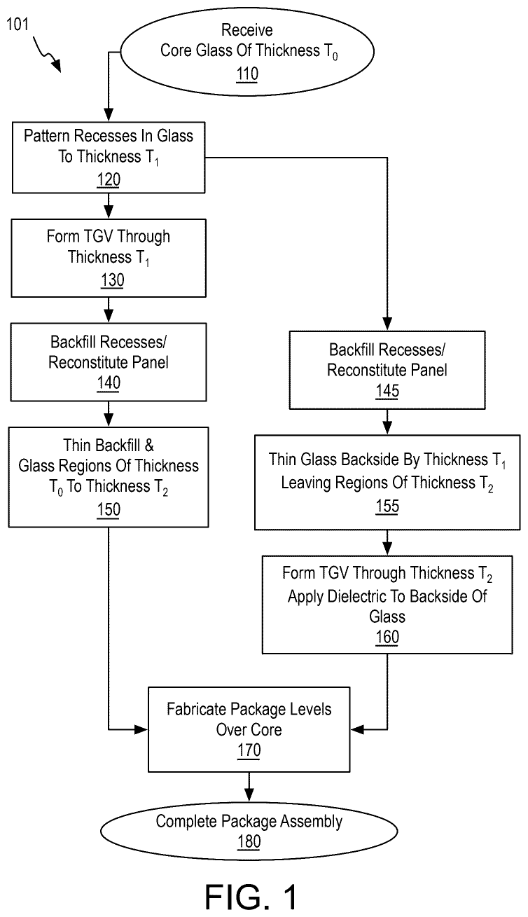

FIG. 1 is a flow diagram illustrating methods 101 of forming an IC die package comprising a package substrate with a thin glass core, in accordance with some embodiments. In methods 101, recesses are patterned into a piece of glass of some initial thickness, thereby reducing the glass thickness only in some limited areas or regions so that the glass may maintain adequate strength for the panel to be reconstituted, for example through the application of a dielectric material on the front and/or backside of the glass. The glass may then be further thinned within a region surrounding the recesses in accordance with some embodiments. Alternatively, the glass may be further thinned even with the recessed region, for example to completely remove some regions of the glass that are not to be retained within an IC package. Following the glass thinning, metallization features and dielectric layers may be built up upon the glass, for example with semi-additive processes (SAP), whereby the thin glass becomes a core of one or more IC die package substrates. One or more IC die may then be assembled with the thin glass core substrate into an IC die package.

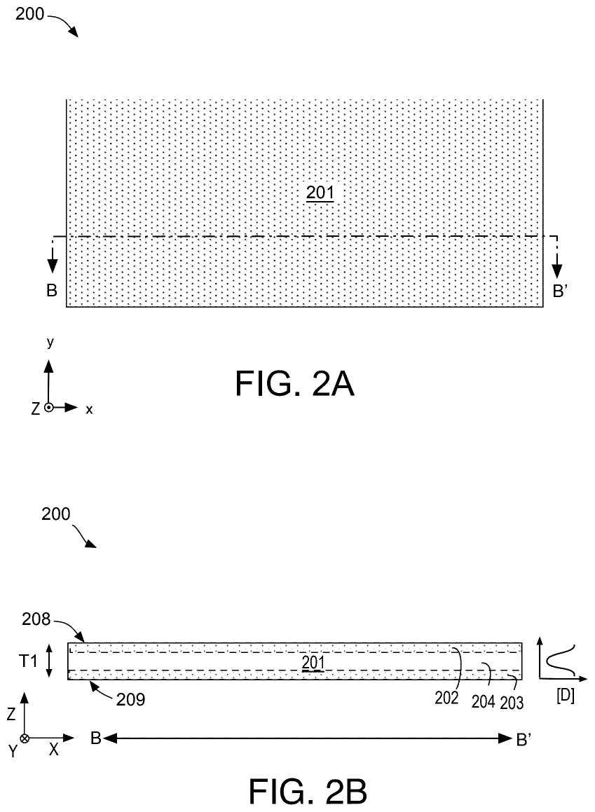

Methods 101 begin where a glass core preform is received at input 110. The preform of core glass received may have any composition and form factor amenable to being further processed into a glass core of a package substrate. FIG. 2A and 2B are plan and cross-sectional views of a glass core preform 200, in accordance with some embodiments. The glass core preform 200 advantageously comprises a single bulk piece of glass 201. Glass core preform 200 may comprise other components than glass 201, such as an edging foil, masking material, etc. In exemplary embodiments, glass 201 is predominantly silica (e.g., silicon and oxygen) and may further include one or more compositional additives, such as, aluminum, beryllium, magnesium, calcium, strontium barium, radium, tin, sodium, silver potassium, boron, phosphorus, zirconium, lithium, titanium, or zinc. Glass 201 may therefore be any of aluminosilicate, borosilicate, alumino-borosilicate, or silica, etc. The composition of glass 201 may be primarily silicon, oxygen, and aluminum, for example. In some advantageous embodiments, glass 201 has a composition of at least 23 weight percent silicon and at least 26 weight percent oxygen, and further comprising at least 5 weight percent aluminum.

In the embodiment illustrated in FIG. 2A, glass preform 200 is rectilinear having any x-axis and y-axis dimensions suitable for panel processing. FIG. 2B illustrates a cross-section through glass 201 along the B-B′ line shown in FIG. 2A. Glass 201 has an initial thickness To between a first (e.g., bottom) glass surface 208 and a second (e.g., top) glass surface 209. In exemplary embodiments, thickness To is less than 2 mm, advantageously less than 1 mm and more advantageously no more than 500 μm (e.g., 200-400 μm). The chemical composition of glass 201 may be substantially homogeneous, or not. Glass 201 may have nanosized aggregates of a different composition than a remainder of the bulk, for example. Glass 201 may also have a varying compositional profile across thickness To. FIG. 2B, for example, illustrates two surface thicknesses or zones 202 and 203. Either (or both) of surface zones 202, 203 may have a different chemical composition than a remainder (e.g., center thickness or zone 204) of glass 201. Surface zones 202, 203 may each have a thickness corresponding to 5-20% of thickness To, for example. As illustrated in the dopant concentration [D] profile of FIG. 2B, surface zone 202 and/or surface zone 203 has a higher concentration of one or more dopants D than the center zone 204 proximal to the half substrate thickness (T₀/2). Dopants D may, for example, increase the hardness of surface zones 202 and/or 203. Although the surface zone dopants may be any of those described above, in some exemplary embodiments surface zone 202 and/or 203 has more of K, Na, or Ag than center zone 204.

In exemplary embodiments, glass 201 is substantially amorphous, but may alternatively have an ordered nanostructure or microstructure. Glass 201 may be quartz glass, for example, having nanocrystalline, polycrystalline, or even substantially monocrystalline microstructure. Aggregates corresponding to compositional inhomogeneity may also have different microstructure than a remainder of glass 201.

Returning to FIG. 1, methods 101 continue at block 120 where recesses are patterned into front and/or back side surfaces of the glass. The recessing process(es) may be of any duration to reduce the thickness of one or more regions of the glass to a predetermined lesser, but non-zero, thickness T₁.

In some embodiments, a mask material is applied to the glass accordingly to any mask patterning process suitable for the mask material. Once masked, any etch process suitable for the chemical composition of the glass may be practiced at block 120 to recess an unmasked portion of the glass. Block 120 may include, for example, one or more processes, such as, but not limited to, wet chemical glass etching (e.g., where spray nozzles spray a wet etchant comprising NaOH or HF) or dry (plasma) glass etching.

In other embodiments, recesses are formed with laser-assisted (enhanced) etching whereby laser energy modifies the glass, for example altering its microstructure. Such processing may not require application of mask material with laser exposure instead rastered over select regions of the glass that are to be thinned. Selective modification of the glass may, for example, form nanopores that accelerate wet chemical etching of the glass. Rather than ablating the glass, laser modification of the glass enables the glass to be subsequently removed with a wet etchant that is selective to other regions of glass that did not receive the laser energy. In some examples, an ultrashort (e.g., picosecond) pulsed laser is operated at pulse durations of around 5 ps. Laser exposure energy may vary with implementation, but in some examples pulse energies are greater than 1000 nJ. Pulse repetition rates may also vary with an exemplary range being 50-250 kHz (e.g., 105 kHz). Although the laser energy may be electromagnetic radiation of any wavelength, in some embodiments the laser energy is in the near-IR range with 1030 nm being one example. Following laser exposure, the glass may be exposed a wet chemical solution (e.g., comprising potassium hydroxide) and regions exposed to the laser energy etch at a rate significantly greater than (e.g., 100-500 times) that of unmodified regions of the glass.

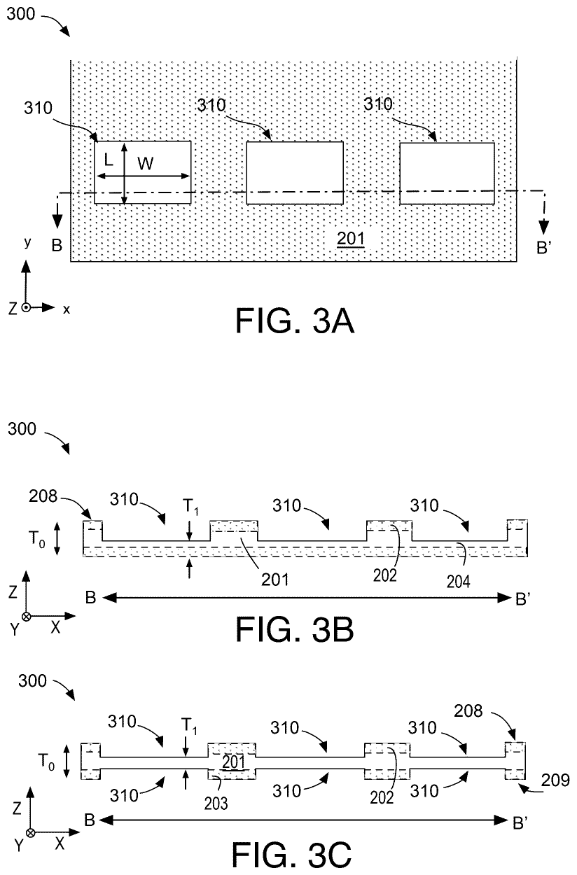

FIG. 3A-3C illustrate recesses 310 in a patterned glass core 300, in accordance with some embodiments. As shown in FIG. 3A, recesses 310 have a length L (e.g., y-dimension) and a width W (e.g., x-dimension). In some embodiments, length L and width W exceed an edge length of an IC die that is to be assembled over glass 201. In some embodiments, length L is within a range of 200 μm to 20 mm and width W is also with a range of 200 μm to 20 mm. As further shown in FIG. 3B, recesses 310 extend through only a portion of glass thickness T₀ with the glass retaining a non-zero thickness T₁ with the recessed region(s). Although thickness T₁ may vary, in exemplary embodiments thickness T₁ is at least 20% thinner than thickness T₀, and advantageously at least 50% thinner. For some examples where thickness T₀ is at least 400 μm, thickness T₁ is no more than 200 μm.

As shown in FIG. 3B, recesses 310 may be formed in only one side of glass 201 (e.g., front side 208). In the illustrated example, an entirety of glass surface zone 202 within recesses 310 has been removed, exposing zone 204 at a bottom of recesses 310. Alternatively, recesses 310 may be formed into both glass front side 208 and glass back side 209, as shown in FIG. 3C. For embodiments with recesses in both sides of glass 201, thickness T₁ may comprise only glass zone 204 with each of glass surface zones 202 and 203 removed from recesses 310.

Returning to FIG. 1, methods continue at either block 130 or block 145 depending on whether or not the glass region recessed at block 120 are to be incorporated within an IC die package. For embodiments of methods 101 where the recessed glass region is to be incorporated within an IC die package, methods 101 continue with block 130. Alternative embodiments of methods 101 where the non-recessed glass region instead of the recessed region is to be incorporated within an IC die package are subsequently described further below.

At block 130, metallization features are formed through the glass thickness T₁. Being of reduced thickness, the metallization features fabricated at block 130 are advantageously of a reduced pitch relative to metallization features that could otherwise be fabricated through glass thickness T₀. Exemplary metallization features include conductive through vias, which may be fabricated with another glass etching process and a subsequent metal deposition. One or more of the processes employed at block 120 to recess regions of the glass may be practiced at block 130 to form through vias. In some examples, via openings are formed at block 130 with a masked dry etch process. In other examples,, via openings are formed with a laser-assisted wet etch. One or more metals may be deposited within the via openings, for example by practicing one or more deposition processes, such as electrolytic plating, physical vapor deposition or chemical vapor deposition.

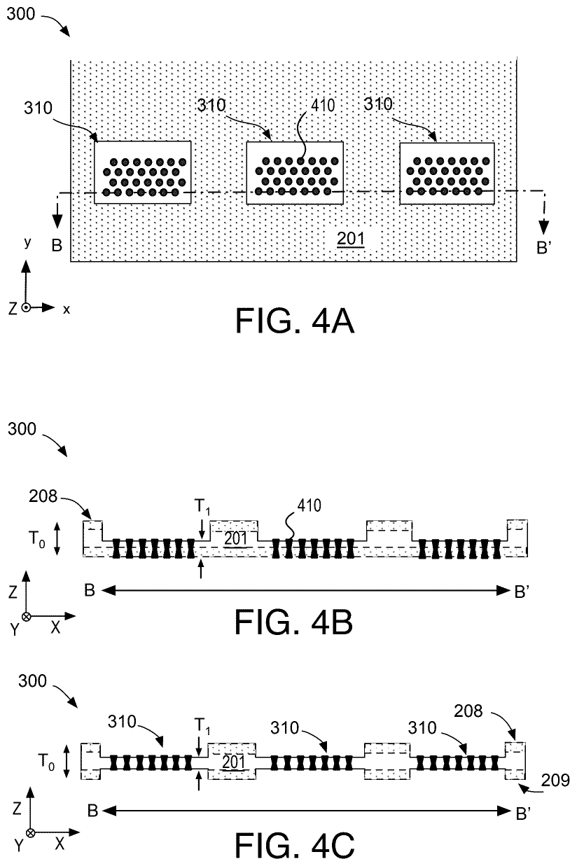

FIG. 4A-4C illustrate formation of metallization features within thin regions of patterned glass core 300, in accordance with some embodiments. The metallization features include at least via metallization features and may further include additional metallization features (e.g., routing lines, etc.). In the illustrated example, the metallization features comprise conductive through vias 410 that extend completely through glass thickness T₁ and are therefore referred to as through-glass vias (TGVs). In the illustrated examples, conductive through vias 410, intersect both opposing glass surfaces 208, 209 and have an hour-glass profile, which is indicative of a double-sided etch process. Conductive through vias 410 may be arrayed over an area, or footprint, of recesses 310. Each conductive through via 410 comprises a conductive material, such as a metal, embedded within glass 201. In some examples, the metal is predominantly copper (Cu). Conductive through vias 410 may have any pitch in the x and/or y dimensions. In some embodiments, conductive through vias 410 have a pitch in at least one of x or y dimensions that is less than 5 μm, advantageously less than 2 μm, more advantageously less than 1 μm. In addition to, or in the alternative to, conductive through vias 410, other non-glass structures, such as other metallization features (e.g., conductive traces or lines) may be embedded within glass thickness T₁.

Following metallization of thin regions of a glass core, methods 101 (FIG. 1) continue at block 140 where the recesses formed at block 120 are at least partially backfilled with a dielectric material. The dielectric material applied to the glass core may also assist in reconstitution of the glass core with other glass cores to form a larger panel that can be parallel processed through the remainder of methods 101. In some embodiments, each glass core is at least slightly smaller than a large format copper clad laminate (CCL) substrate having a length of about 510 mm and a width of about 515 mm. Depending on the dimensions of a glass core, one or more glass cores may be reconstituted into a panel approximately the same size as a large format CCL substrate panel.

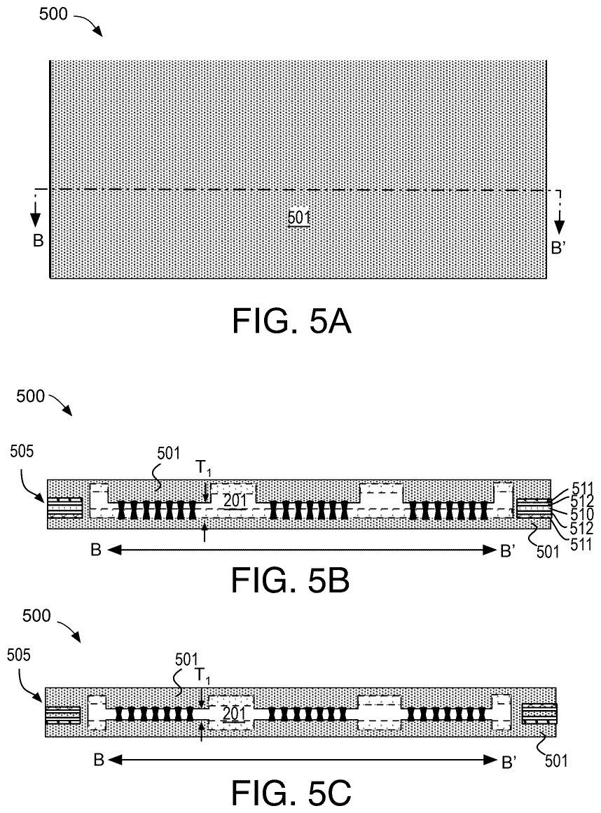

In some embodiments, a glass core is reconstituted into a hybrid panel that further includes a non-glass frame. In embodiments where a plurality of glass cores are reconstituted within a perimeter frame, the length and width of each piece of glass may be scaled down (e.g., to an approximate 200-250 mm quadrant of a large format package substrate panel, or an approximate 100-125 mm 1/16^{th} sector of a large format package substrate panel) and reconstituted within the frame through the further application of dielectric material. FIG. 5A-5C are plan and cross-sectional views of a thin glass core panel 500, in accordance with some embodiments where a dielectric material 501 has been applied over a single piece of glass 201 positioned within a perimeter frame 505. As noted above, glass dimensions may be scaled such that more than one piece of glass may be within frame 505.

In exemplary embodiments, perimeter frame 505 is a unitary body comprising one or more contiguous material layers. In the examples illustrated in FIG. 5B and 5C, frame 505 is a laminate of metallization and dielectric material, and may be any known CCL, for example. As further illustrated in FIG. 5B, perimeter frame 505 may include a rigid core 510. For cored embodiments, a core may be an epoxy-based laminate (e.g., FR4), for example. Alternatively, perimeter frame 505 or may be coreless. In cored embodiments, layers of metallization 511 and layers of dielectric material 512 may have been built up on one or more sides of core 510 to reach a frame thickness compatible with glass thickness T₁. In coreless embodiments, frame 505 may consist of only metallization layers 511 and/or dielectric material layers 512. In addition to protecting edges of glass 201, frame 505 may provide mechanical support to glass 201 as it is further thinned in accordance with methods 101.

As shown both for single-sided recesses (FIG. 5B) and double-sided recesses (FIG. 5C), dielectric material 501 extends over top and bottom surfaces of glass 201 and frame 505, adhering these components together into a panel. Dielectric material 501 at least partially backfills any gap between edges of glass 201 and frame 505. In some embodiments, a dry dielectric film is applied (e.g., laminated) over both frame 505 and glass 201. In other embodiments, a flowable epoxy is applied over both frame 505 and glass 201, and subsequently cured according to any suitable molding processing. Dielectric material 501 may be an organic dielectric, such as, an epoxy resin, phenolic-glass, or a resinous film such as the GX-series films commercially available from Ajinomoto Fine-Techno Co., Inc. (ABF). Dielectric material 501 may comprise epoxy resins (e.g., an acrylate of novolac such as epoxy phenol novolacs (EPN) or epoxy cresol novolacs (ECN)). In other examples, dielectric material 501 includes aliphatic epoxy resin, which may be monofunctional (e.g., dodecanol glycidyl ether), difunctional (butanediol diglycidyl ether), or have higher functionality (e.g., trimethylolpropane triglycidyl ether).

Returning to FIG. 1, methods 101 continue at block 150 where the dielectric material applied at block 140 is thinned, along with thicker regions of the glass core that are exposed with thinning of the dielectric material. Any mechanical and/or chemical planarization or etchback process suitable for the materials present may be practiced at block 150, for example to reduce a remainder of the glass core to a thickness T₂ that is significantly less than the initial glass thickness T₀ (as received at input 110).

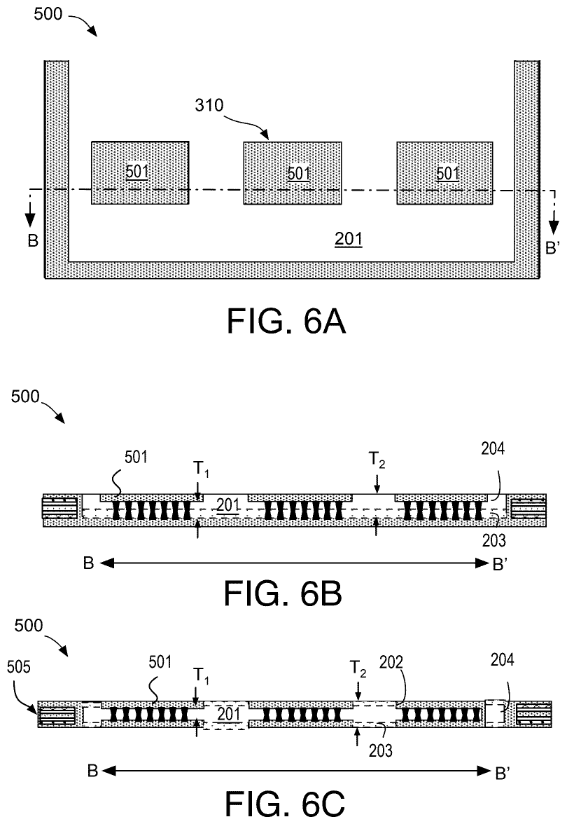

FIG. 6A-6C illustrate an exemplary panel-level thinning of thin glass core 500, in accordance with some embodiments. As shown, dielectric material 501 is retained only within recessed regions 310 and adjacent to an edge of glass 201. For hybrid-panel embodiments, dielectric material 501 may also be retained over frame 505, as illustrated. As shown in FIG. 6B, planarization may be performed on only one (e.g., top) side of glass 201, reducing regions of thickness T₀ to thickness T₂. Accordingly, glass thickness zone 204 may be exposed between recesses 310 while surface zone 203 may be retained on a backside of glass 201. As shown in FIG. 6C, for embodiments with recesses 310 on both sides of glass 201, planarization may be performed on both top and bottom sides of glass 201, again reducing regions of thickness T₀ to a thickness T₂. Accordingly, either or both of glass surface zones 202 and 203 may be thinned and/or completely removed from between recesses 310. For both single-sided (e.g., FIG. 6B) and double-sided (e.g., FIG. 6C) embodiments, thickness T₂ is advantageously no more than 50 μm greater than thickness T₁. In some embodiments, thickness T₂ is no more than 25 μm greater than thickness T₁.

With a glass core now fully thinned, methods 101 (FIG. 1) continue at block 170 where package metallization and insulator levels (layers) are built up over the glass core. Package build up may be according to any techniques known to be suitable for advanced package substrates. For example, dielectric material layers may be deposited and patterned, and electrically conductive materials may then be deposited upon the patterned dielectric surface to form a routing or redistribution metallization layers. Conductive material layers, for example comprising predominantly Cu, may be deposited by any known technique, such as plating. Following package build-up, methods 101 end at output 180 where IC die assembly and/or package singulation is completed according to any known techniques.

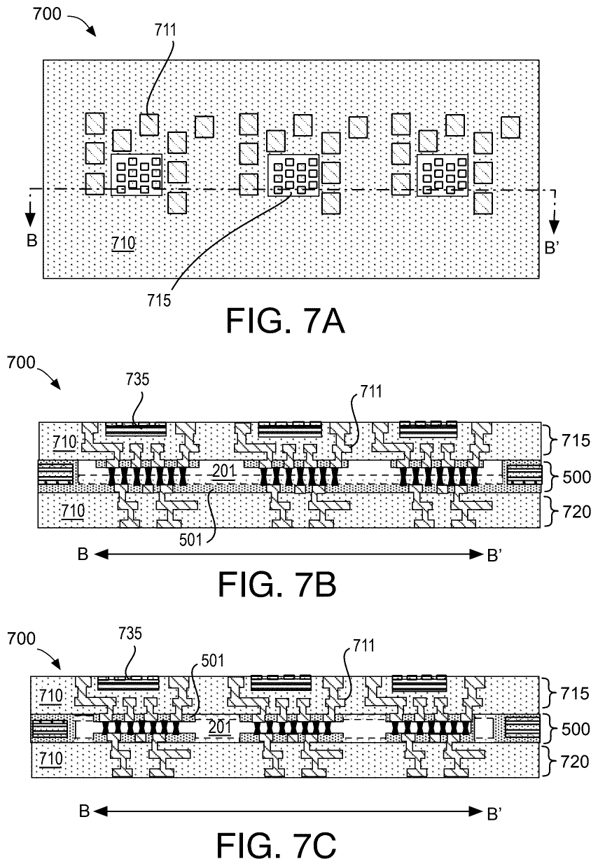

FIG. 7A-7C illustrate a build-up of an RDL structure 715 on a first (e.g., front) side of thin glass core panel 500 to form a package substrate panel 700, in accordance with some embodiments. RDL structure 715 includes a plurality of levels of metallization features 711 embedded within dielectric material 501 as well as additional dielectric material 710. In exemplary embodiments, metallization features 711 are predominantly Cu and dielectric material 710 is an organic dielectric material. Dielectric material 710 may have any of the compositions described for dielectric material 501 and, in some embodiments, dielectric material 710 has the same composition as dielectric material 501. As further illustrated in FIG. 7B-7C, another RDL structure 720 may be concurrently formed on a second (e.g., back) side of thin glass core panel 500.

For embodiments where glass 201 was recessed on one surface of glass 201 (FIG. 7B), dielectric material 710 on the top side of package panel 700 is in direct contact with the region of glass 201 of greater thickness (T₂). Dielectric material 710 on the bottom side of package panel 700 is separated from glass 201 by intervening dielectric material 501. For embodiments where glass 201 was recessed on both surfaces of glass 201 (FIG. 7C), dielectric material 710 on both the top and bottom sides of package panel 700 is in direct contact with the region of glass 201 of greater thickness (T₂).

Following (or during) package build-up, one or more devices may be embedded within a package. In the examples illustrated in FIG. 7B-7C, an interconnect bridge die 735 is embedded within package dielectric material 710. An interconnect bridge die may have interconnect routing features fabricated at monolithic chip-scale, which may be of significantly higher density than the routing of package build-up. Interconnect bridge die 735 is one example of an embedded IC die and any IC die may be similarly embedded into package dielectric material 710 according to any known techniques.

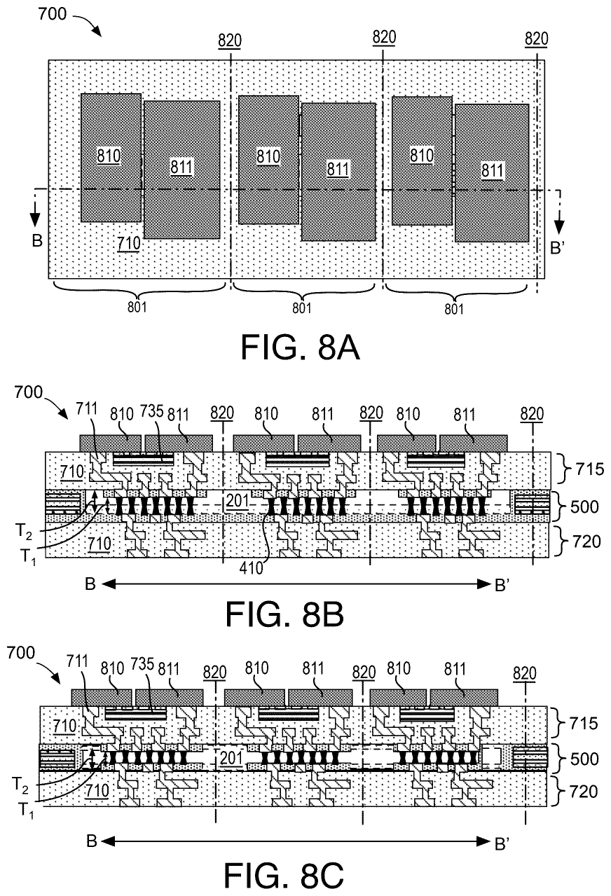

FIG. 8A-8C are plan and cross-sectional views illustrating assembly of IC die 810 and 811 upon package panel 700, in accordance with some exemplary embodiments. In this example, each of IC die 810, 811 are electrically interconnected to embedded interconnect die 735. Each of IC die 810, 811 are also electrically interconnected to package metallization 711 that is further coupled to conductive TGVs 410. As further illustrated, package panel 700 may be singulated along kerfs 820 to form discrete thin glass-core IC packages 801. Depending on the structure of the package panel 700 (e.g., the lateral dimensions of glass 201) one or more thin glass-core IC packages 801 may be formed from a single piece of glass 201. A single thin glass-core IC package 801 may therefore evolve from a single piece of glass 201, or a plurality (e.g., 2, 3, 4, 16, etc.) thin glass-core packages 801 may evolve from a single piece of glass. A thin glass-core package 801 may be singulated to eliminate all of frame 505, or some portion of frame 505 may be retained within one or more package 801. However, each package 801 retains glass core regions of both thickness T₁ and thickness T₂. More specifically, each package 801 comprises a thinner glass core region proximal to a center of the package footprint and a thicker glass core region at a periphery of the package footprint. In some embodiments, the thicker glass core region having glass thickness T₂ substantially surrounds the thinner glass core region having glass thickness T₁.

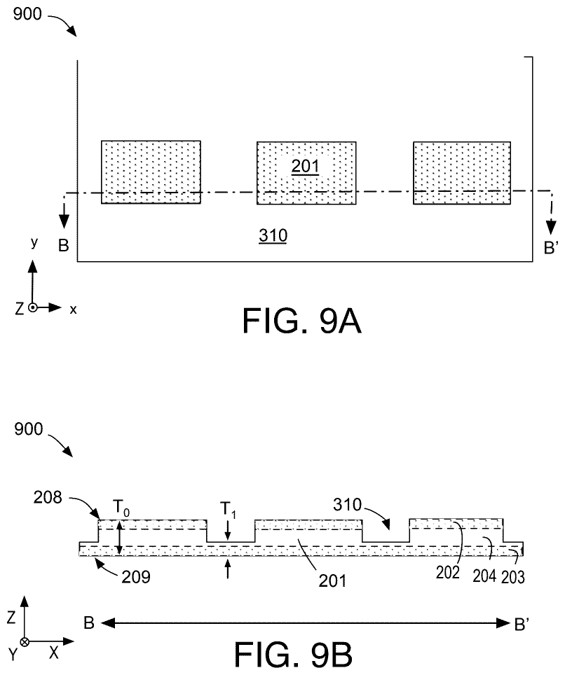

Returning to FIG. 1 for alternative embodiments where a non-recessed region of glass instead of a recessed region of glass is to be retained within an IC die package, the pattern etched into the glass at block 120 may be substantially the inverse of the pattern etched for embodiments where the recessed region is retained in an IC die package. FIG. 9A and 9B illustrate an exemplary patterned glass panel 900 formed from glass core preform 200 (FIG. 2A, 2B) by etching recesses 310. In this example, recesses 310 are patterned only into glass front side 208. For embodiments where glass 201 comprises surface dopant zones 202 and 203, recesses 310 may extend through surface zone 202 and expose zone 204. Recesses 310 are again etched to a depth that results in underlying glass 201 to have a reduced thickness T₁. Thickness T₁ may be less than initial glass thickness T₀, for example by the same amount previously described elsewhere herein.

With one or more recesses patterned the glass, methods 101 (FIG. 1) progress from block 120 to block 145 where a recess is at least partially backfilled with dielectric material. The dielectric material applied at block 145 may also be utilized to reconstitute a patterned glass core into a larger panel of multiple glass cores for subsequent processing. In some embodiments, the dielectric material applied at block 145 adheres one patterned glass core to another patterned glass core. In some hybrid-panel embodiments, the dielectric material applied at block 145 adheres one or more patterned glass cores to a non-glass frame. As previously described elsewhere herein, the length and width of each piece of glass within a panel (hybrid or otherwise) may be scaled down (e.g., to an approximate 200-250 mm quadrant of a large format package substrate panel, or an approximate 100-125 mm 1/16^{th} sector of a large format package substrate panel).

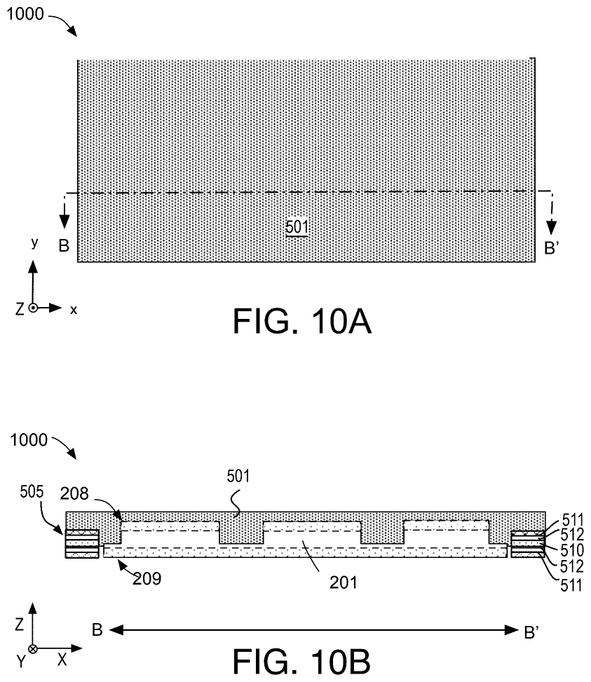

FIG. 10A-10B illustrate reconstitution of a patterned glass core panel 1000 comprising one or more patterned glass cores and a non-glass frame 505. Although FIG. 10A-10B illustrate a single piece of glass 201 within perimeter frame 505 and embedded within a dielectric material 501, glass dimensions may be scaled such that any number of glass units may be similarly reconstituted with frame 505. In the example illustrated in FIG. 10B, perimeter frame 505 is a laminate of metallization and dielectric material that includes a rigid core 510. Build-up layers of metallization 511 and layers of dielectric material 512 are on sides of core 510 provide a frame thickness that is compatible with glass thickness T₁. Notably, dielectric material 501 has been applied only to one (e.g., front) side of glass 201 and frame 505.

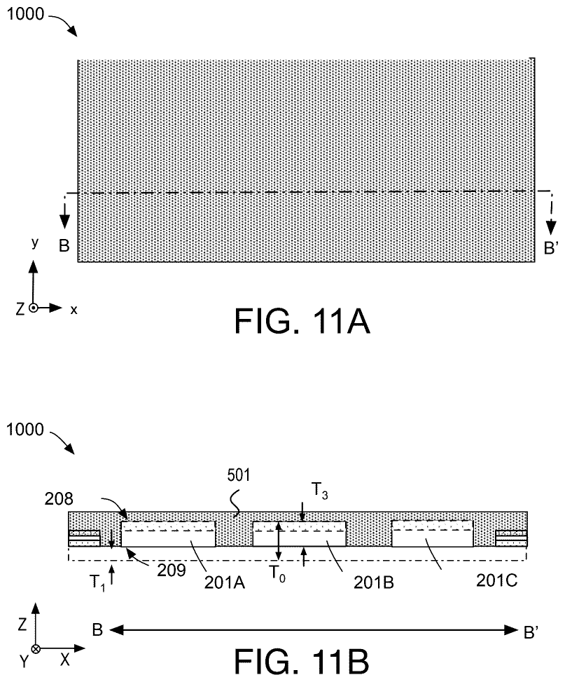

Returning to FIG. 1, methods 101 continue at block 155 where glass thinning is performed from the (planar) side the glass core that was not patterned in block 120. Any core or panel level thinning process suitable for the glass composition may be practiced at block 155. In some examples, a grinding and/or chemical/mechanical polishing process is performed. In other examples, a wet chemical spray etch process is performed. FIG. 11A-11B illustrate thinning of glass core panel 1000, in accordance with some embodiments. As shown in dashed line, a thickness T₁ is removed from glass 201 so that only regions of initial thickness T₀ retain a non-zero thickness T₃ following thinning from backside 209. Accordingly, a unitary body of patterned glass 201 is thinned to form a plurality of reconstituted thin glass bodies 201A, 201B and 201C, which remain embedded in dielectric material 501. Thickness T₃ may vary with implementation, but in some exemplary embodiments thickness T₃ is at least 20% thinner than thickness T₀, and advantageously at least 50% thinner. For some examples where thickness T₀ is at least 400 μm, thickness T₃ is less than 200 μm.

Returning to FIG. 1, methods 101 continue at block 160 where dielectric material is formed on a backside of the thin glass and metallization features are formed through the thin glass, and through any dielectric material covering one or more sides of the thin glass. The dielectric material deposited at block 160 may be substantially the same as that deposited at block 145, for example. With the glass having reduced thickness, the metallization features fabricated at block 160 are advantageously of a reduced pitch relative to metallization features that could otherwise be fabricated through glass thickness T₀. Exemplary metallization features include conductive through vias, which may be fabricated with another glass etching process and a subsequent metal deposition. In some embodiments, via openings are patterned in the thin glass from one side while in other embodiments the via openings are patterned from both sides of the glass. One or more of the processes employed at block 120 to recess regions of the glass may be practiced at block 160 to form through vias. In some examples, via openings are formed at block 160 with a masked dry etch process. In other examples, a laser-assisted wet etch may be practiced. One or more metals may be deposited within the via openings, for example by practicing one or more deposition processes, such as electrolytic plating, physical vapor deposition or chemical vapor deposition.

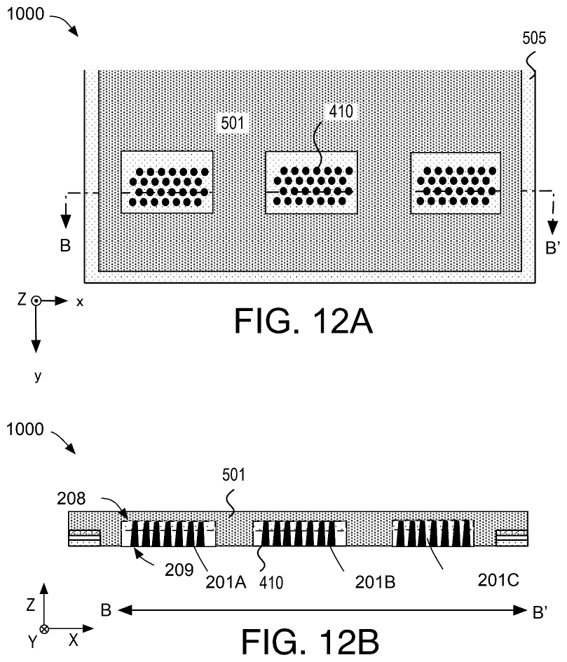

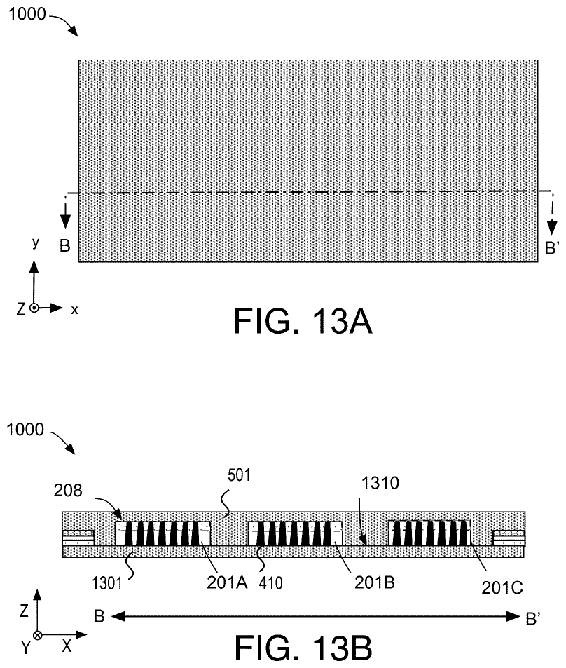

FIG. 12A-12B illustrate formation of metallization features within thin glass regions of glass core panel 1000, in accordance with some embodiments. In this example, the metallization features comprise conductive through-glass vias 410 that extend completely through glass thickness T₃. Conductive through-glass vias 410, intersect both opposing glass surfaces 208, 209 and have a sidewall profile that is monotonically tapered to smaller diameters with depth from surface 209, which is indicative of a single-sided etch process. FIG. 13A-13B further illustrate an application of a second dielectric material layer 1301 over glass surface 209. Dielectric material layer 1301 also extends over at least a portion of frame 505. The composition of dielectric material layer 1301 may vary with implementation. In some embodiments, dielectric material layer 1301 is an organic dielectric material, such as any of the compositions listed above for dielectric material 501. In some embodiments, dielectric material layer 1301 is of the same composition as dielectric material layer 501. Independent of compositional similarity, an interface 1310 may be visible where dielectric material layer 1301 contacts dielectric material layer 501.

Although FIG. 12A-12B and 13A-13B illustrate one example where conductive through vias 410 are formed prior to formation of dielectric material layer 1301. In alternative embodiments, conductive through vias 410 may be formed subsequent to formation of dielectric material layer 1301. In some alternative embodiments, vias 410 may instead have an hour-glass sidewall profile indicative of a double-side via etch process.

Through vias 410 may be arrayed over an area, or footprint, of glass units 201A, 201B and 201C. Each of conductive through via 410 may comprise a conductive material, such as a metal, embedded within the glass. In some examples, the metal is predominantly copper (Cu). Conductive through vias 410 may have any pitch in the x and/or y dimensions. In some embodiments, conductive through vias 410 have a pitch in at least one of x or y dimensions that is less than 5 μm, advantageously less than 2 μm, more advantageously less than 1 μm. In addition to, or in the alternative to, conductive through vias 410 other non-glass structures, such as other metallization features (e.g., conductive traces or lines), may also be embedded within glass thickness T₃.

With the glass thinned, methods 101 (FIG. 1) similarly continue at block 170 where package metallization and insulator levels or layers are built up over the glass core. Package build up may be according to any techniques known to be suitable for advanced package substrates. For example, dielectric material may be deposited and patterned, and electrically conductive materials may be deposited upon the patterned dielectric surface to form a routing or redistribution metallization layers. Conductive material layers, for example comprising predominantly Cu, may be deposited by any known technique, such as plating. Following package build-up methods 101 again end at output 180 where IC die assembly and/or package singulation is completed according to any known techniques.

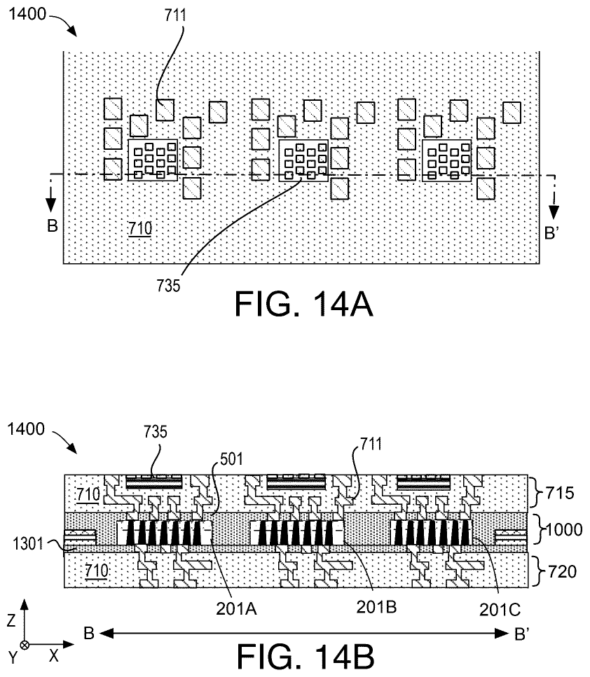

FIG. 14A-14B illustrate a build-up of an RDL structure 715 on a first (e.g., front) side of thin glass core panel 1000 to form a package panel 1400, in accordance with some embodiments. RDL structure 715 includes a plurality of levels of metallization features 711 embedded within dielectric material 501 as well as additional dielectric material 710. In exemplary embodiments, metallization features 711 are predominantly Cu and dielectric material 710 is an organic dielectric material. Dielectric material 710 may have any of the compositions described elsewhere for dielectric material 501. In some embodiments, dielectric material 710 has the same composition as dielectric material 501 and/or dielectric material 1301. As further illustrated in FIG. 14A-14B, RDL structure 720 may be concurrently formed on a second (e.g., back) side of thin glass core panel 1400.

In contrast to the embodiments illustrated in FIG. 7A-7C, glass 201A-201C (FIG. 14A-14B) has substantially a uniform thickness (e.g., T₂). The location of interface 1310 relative to surfaces of glass 201A-201C is indicative of the two-stage patterning and thinning process enlisted by methods 101 (FIG. 1). As further illustrated in FIG. 14B, following (or during) package build-up, one or more devices may be embedded within a package. In the examples illustrated in FIG. 14A-14B, an interconnect bridge die 735 is embedded within package dielectric material 710. Interconnect bridge die 735 is one example of an embedded IC die and any IC die may be similarly embedded into package dielectric material 710 according to any known techniques.

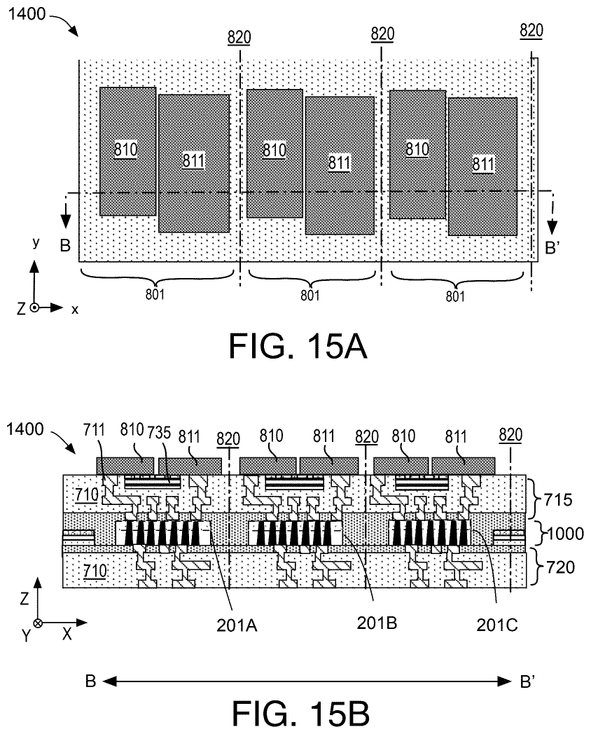

FIG. 15A-15B are plan and cross-sectional views illustrating assembly of IC die 810 and 811 upon package panel 1400, in accordance with some exemplary embodiments. In this example, each of IC die 810, 811 are electrically interconnected to embedded interconnect die 735. Each of IC die 810, 811 are also electrically interconnected to package metallization 711 that is further coupled to conductive TGVs 410. As further illustrated, package panel 700 may be singulated along kerfs 820 to form discrete thin glass-core IC packages 801. Depending on the structure of the package panel 1400 (e.g., the lateral dimensions of glass 201A-201C) any number of glass-core IC packages 801 may be formed from panel 1400. In the illustrated example, a single thin glass-core IC package 801 evolves from a single piece of glass 201A, 201B or 201C. A thin glass-core package 801 may be singulated to eliminate all of frame 505, or some portion of frame 505 may be retained within one or more package 801.

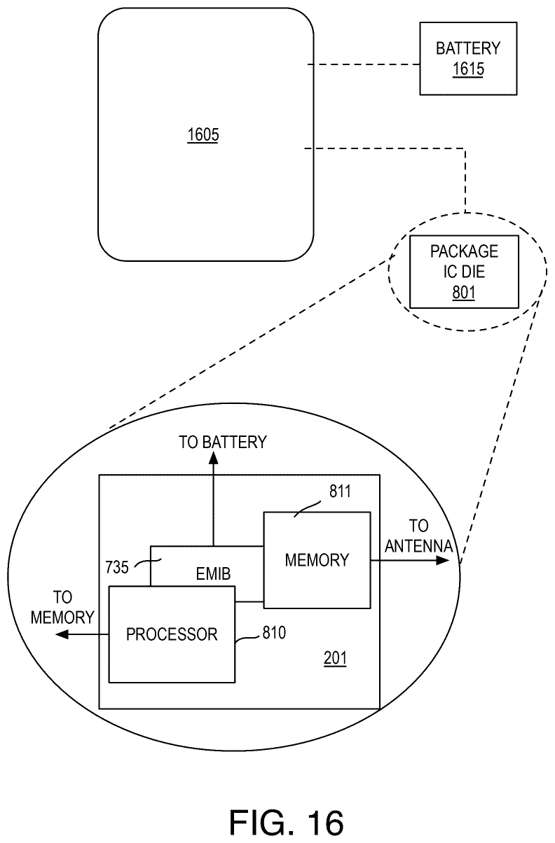

The thin glass core IC die packages described above may be incorporated into any electronic device or system. FIG. 16 illustrates a system in which a mobile computing platform or data server machine 1605 includes IC die package 801 comprising a thin glass core in accordance with one or more of the embodiments described elsewhere herein. A server machine may be any commercial server, for example including any number of high-performance computing platforms within a rack and networked together for electronic data processing. A mobile computing platform may be any portable device configured for each of electronic data display, electronic data processing, wireless electronic data transmission, or the like. For example, a mobile computing platform may be any of a tablet, a smart phone, laptop computer, etc., and may include a display screen (e.g., a capacitive, inductive, resistive, or optical touchscreen), IC die package 801, and a battery 1615.

As shown in the expanded view, IC die package 801 may include memory circuitry (e.g., RAM) on IC die 810, and/or a processor circuitry (e.g., a microprocessor, a multi-core microprocessor, graphics processor, or the like) on IC die 811. IC die package 801 includes a thin glass core 201 including features in accordance with one or more embodiments described elsewhere herein. Memory circuitry and processor circuitry are coupled to an interconnect bridge die 735, which in some embodiments is embedded within a substrate of IC die package 801. In some embodiments, IC die package 801 further hosts an embedded device, such as a MIM capacitor array that is at least partially embedded within glass core 201 or within a build-up layer thereon.

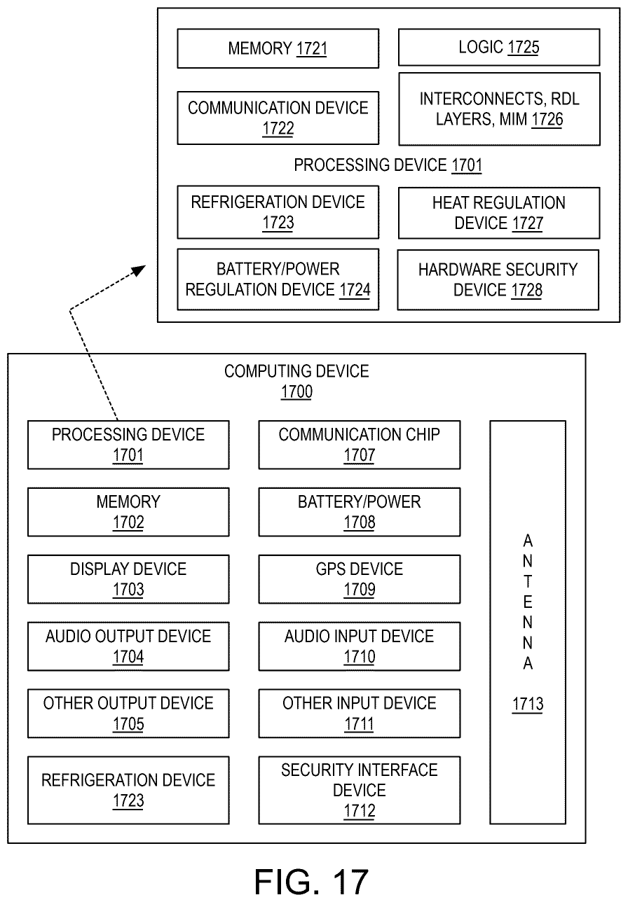

FIG. 17 is a block diagram of a computing device 1700 in accordance with some embodiments. For example, one or more components of computing device 1700 may include any of the glass core structures discussed elsewhere herein. A number of components are illustrated in FIG. 17, but any one or more of these components may be omitted or duplicated, as suitable for the application. In some embodiments, some of the components included in computing device 1700 may be attached to one or more printed circuit boards (e.g., a motherboard). In some embodiments, various ones of these components may be fabricated onto a single system-on-a-chip (SoC) die or implemented with a disintegrated plurality of chiplets or tiles packaged together. Additionally, in various embodiments, computing device 1700 may not include one or more of the components illustrated in FIG. 17, but computing device 1700 may include interface circuitry for coupling to the one or more components. For example, computing device 1700 may not include a display device 1703, but may include display device interface circuitry (e.g., a connector and driver circuitry) to which display device 1703 may be coupled.

Computing device 1700 may include a processing device 1701 (e.g., one or more processing devices). As used herein, the term processing device or processor indicates a device that processes electronic data from registers and/or memory to transform that electronic data into other electronic data that may be stored in registers and/or memory. Processing device 1701 may include a memory 1702, a communication device 1722, a refrigeration/active cooling device 1723, a battery/power regulation device 1724, logic 1725, interconnects 1726, a heat regulation device 1727, and a hardware security device 1728.

Processing device 1701 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable compute units.

Processing device 1701 may include a memory 1702, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, processing device 1701 shares a package with memory 1702. This memory may be used as cache memory and may include embedded dynamic random-access memory (eDRAM) or spin transfer torque magnetic random-access memory (STT-M RAM).

Computing device 1700 may include a heat regulation/refrigeration device 1723. Heat regulation/refrigeration device 1723 may maintain processing device 1701 (and/or other components of computing device 1700) at a predetermined low temperature during operation. This predetermined low temperature may be any temperature discussed elsewhere herein.

In some embodiments, computing device 1700 may include a communication chip 1707 (e.g., one or more communication chips). For example, the communication chip 1707 may be configured for managing wireless communications for the transfer of data to and from computing device 1700. The term “wireless” and its derivatives may be used to describe circuits, devices, systems, methods, techniques, communications channels, etc., that may communicate data through the use of modulated electromagnetic radiation through a nonsolid medium.

Computing device 1700 includes antenna 1713 may facilitate communication between one or more instances of processing device 1701 and/or one or more instances of memory 1721, for example.

Computing device 1700 may include battery/power circuitry 1708. Battery/power circuitry 1708 may include one or more energy storage devices (e.g., batteries or capacitors) and/or circuitry for coupling components of computing device 1700 to an energy source separate from computing device 1700 (e.g., AC line power).

Computing device 1700 may include a display device 1703 (or corresponding interface circuitry, as discussed above). Display device 1703 may include any visual indicators, such as a heads-up display, a computer monitor, a projector, a touchscreen display, a liquid crystal display (LCD), a light-emitting diode display, or a flat panel display, for example.

Computing device 1700 may include an audio output device 1704 (or corresponding interface circuitry, as discussed above). Audio output device 1704 may include any device that generates an audible indicator, such as speakers, headsets, or earbuds, for example.

Computing device 1700 may include an audio input device 1710 (or corresponding interface circuitry, as discussed above). Audio input device 1710 may include any device that generates a signal representative of a sound, such as microphones, microphone arrays, or digital instruments (e.g., instruments having a musical instrument digital interface (MIDI) output).

Computing device 1700 may include a global positioning system (GPS) device 1709 (or corresponding interface circuitry, as discussed above). GPS device 1709 may be in communication with a satellite-based system and may receive a location of computing device 1700.

Computing device 1700 may include another output device 1705 (or corresponding interface circuitry, as discussed above). Examples include an audio codec, a video codec, a printer, a wired or wireless transmitter for providing information to other devices, or an additional storage device.

Computing device 1700 may include another input device 1711 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1700 may include a security interface device 1712. Security interface device 1712 may include any device that provides security measures for computing device 1700 such as intrusion detection, biometric validation, security encode or decode, managing access lists, malware detection, or spyware detection.

Computing device 1700, or a subset of its components, may have any appropriate form factor, such as a server or other networked computing component, a mobile device, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that embodiments described herein may be practiced with modification and alteration without departing from the scope of the appended claims. For example, the above embodiments may include specific combinations of features as further provided below.

In first examples an apparatus comprises an integrated circuit (IC) die and a package substrate coupled to the IC die. The package substrate comprises a glass core having a thickness of no more than 200 μm, a via metallization features extending through the thickness of the glass core, an organic dielectric material over at least one surface of the glass core, and a level of routing metallization features over at least the top surface of the glass core, the routing metallization features electrically coupled to the via metallization features.

In second examples, for any of the first examples the thickness is a first thickness proximal to a center of the package substrate and the glass core comprises a second thickness, greater than the first thickness, proximal to a periphery of the package substrate.

In third examples, for any of the second examples a difference between the first and second thicknesses is no more than 50 μm.

In fourth examples, for any of the second or third examples a non-planarity on one side of the glass core comprises the difference between the first and second thickness, and a second side of the glass core is substantially planar between the center of the package and the periphery of the package.

In fifth examples, for any of the third through fifth examples the via metallization features are exclusively within the center of the package.

In sixth examples, for any of the second through fifth examples the apparatus further comprises a first dielectric material layer over, and in contact with, a first portion of the glass core having the first thickness, and a second dielectric material layer over, and in contact with, a second portion of the glass core having the second thickness. The second dielectric material layer also extends over, and is in contact with, the first dielectric material layer.

In seventh examples, for any of the first through sixth examples the apparatus further comprises one of more levels of interconnect metallization features between the glass core and the IC die, at least one of the interconnect metallization features electrically coupled to at least one of the via metallization features.

In eighth examples, for any of the first examples the glass core has a thickness that is substantially constant over an entirety of the glass core.

In ninth examples, for any of the eighth examples the apparatus comprise a first dielectric material layer over, and in contact with, a first side of the glass core, and a second dielectric material layer over, and in contact with, a second side of the glass core. Adjacent to an edge of the glass core, the first dielectric material layer is in contact with the second dielectric material layer along a material interface.

In tenth examples, for any of the ninth examples the material interface is substantially planar with the first side of the glass core, or substantially planar with the second side of the glass core.

In eleventh examples, for any of the eighth through tenth examples the apparatus further comprises a non-glass frame adjacent to the edge of the glass core.

In twelfth examples, for any of the eighth through eleventh examples the apparatus further comprises one of more levels of interconnect metallization features between the glass core and the IC die, at least one of the interconnect metallization features electrically coupled to at least one of the via metallization features.

In thirteenth examples, an integrated circuit (IC) die package panel comprises one or more units of glass having thickness of no more than 200 μm, a plurality of conductive vias extending through the thickness of each of the units of glass, and a dielectric material in direct contact with at least one side of each of the units of glass and also between edges of adjacent ones of the units of glass.

In fourteenth examples, for any of the thirteenth examples the units of glass have a first thickness in a first region of the glass, and a second thickness, greater than the first thickness, in a second region of the glass.

In fifteenth examples, for any of the thirteenth through fourteenth examples the second region is at the periphery of the first region in each of the units of glass.

In sixteenth examples, a method comprises receiving a glass core of a first thickness between a planar top surface and a planar bottom surface, and etching a recess into at least one of the top surface or the bottom surface of the glass core. The glass core has a second thickness within an area of the recess and the method comprises forming a dielectric material layer over at least one of the top surface or the bottom surface of the glass core, the dielectric material layer at least partially backfilling the recess. The method comprises thinning, to a third thickness, a region of the glass core outside of the recess.

In seventeenth examples, for any of the sixteenth examples thinning the region of the glass core comprises removing the second thickness from an entirety of the glass core.

In eighteenth examples, for any of the sixteenth through seventeenth examples the method comprises forming conductive through vias the region of the glass core outside of the recess.

In nineteenth examples, for any of the sixteenth through eighteenth examples the method comprises forming conductive through vias within the area of the recess, the conductive through vias extending through the second thickness.

In twentieth examples, for any of the sixteenth through nineteenth examples the method comprises forming a hybrid panel by joining the glass core with a non-glass frame that surrounds a perimeter of the glass core.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should, therefore, be determined with reference to the appended claims.

What is claimed is:

1. An apparatus, comprising:
an integrated circuit (IC) die; and
a package substrate coupled to the IC die, wherein the package substrate comprises:
a glass core having a thickness of no more than 200 μm;
a via metallization features extending through the thickness of the glass core;
an organic dielectric material over at least one surface of the glass core; and
a level of routing metallization features over at least one surface of the glass core, the routing metallization features electrically coupled to the via metallization features.

2. The apparatus of claim 1, wherein the thickness is a first thickness proximal to a center of the package substrate and wherein the glass core comprises a second thickness, greater than the first thickness, proximal to a periphery of the package substrate.

3. The apparatus of claim 2, wherein a difference between the first thickness and the second thickness is no more than 50 μm.

4. The apparatus of claim 3, wherein non-planarity on one side of the glass core comprises the difference between the first thickness and the second thickness, and a second side of the glass core is substantially planar between a center of the package and a periphery of the package.

5. The apparatus of claim 3, wherein the via metallization features are exclusively within the center of the package.

6. The apparatus of claim 2, further comprising:
a first dielectric material layer over, and in contact with, a first portion of the glass core having the first thickness; and
a second dielectric material layer over, and in contact with, a second portion of the glass core having the second thickness, wherein the second dielectric material layer also extends over, and is in contact with, the first dielectric material layer.

7. The apparatus of claim 1, further comprising one of more levels of interconnect metallization features between the glass core and the IC die, at least one of the interconnect metallization features electrically coupled to at least one of the via metallization features.

8. The apparatus of claim 1, wherein the glass core has a thickness that is substantially constant over an entirety of the glass core.

9. The apparatus of claim 8, further comprising:
a first dielectric material layer over, and in contact with, a first side of the glass core; and
a second dielectric material layer over, and in contact with, a second side of the glass core, wherein, adjacent to an edge of the glass core, the first dielectric material layer is in contact with the second dielectric material layer along a material interface.

10. The apparatus of claim 9, wherein the material interface is substantially planar with the first side of the glass core, or substantially planar with the second side of the glass core.

11. The apparatus of claim 9, further comprising a non-glass frame adjacent to the edge of the glass core.

12. The apparatus of claim 8, further comprising one of more levels of interconnect metallization features between the glass core and the IC die, at least one of the interconnect metallization features electrically coupled to at least one of the via metallization features.

13. An integrated circuit (IC) die package panel, comprising:
one or more units of glass having thickness of no more than 200 μm;
a plurality of conductive vias extending through the thickness of each of the units of glass; and
a dielectric material in direct contact with at least one side of each of the units of glass and also between edges of adjacent ones of the units of glass.

14. The IC die package panel of claim 13, wherein the units of glass have a first thickness in a first region of the glass, and a second thickness, greater than the first thickness, in a second region of the glass.

15. The IC die package panel of claim 14, wherein the second region is at a periphery of the first region in each of the units of glass.

16. A method comprising:
receiving a glass core of a first thickness between a planar top surface and a planar bottom surface;
etching a recess into at least one of the top surface or the bottom surface of the glass core, the glass core having a second thickness within an area of the recess;
forming a dielectric material layer over at least one of the top surface or the bottom surface of the glass core, the dielectric material layer at least partially backfilling the recess; and
thinning, to a third thickness, a region of the glass core outside of the recess.

17. The method of claim 16, wherein thinning the region of the glass core comprises removing the second thickness from an entirety of the glass core.

18. The method of claim 17, further comprising forming conductive through vias the region of the glass core outside of the recess.

19. The method of claim 16, further comprising forming conductive through vias within the area of the recess, the conductive through vias extending through the second thickness.

20. The method of claim 16, further comprising forming a hybrid panel by joining the glass core with a non-glass frame that surrounds a perimeter of the glass core.
